(19) United States
(12) Patent Application Publication
(10) Pub. No.: US 2020/0231800 A1
(43) Pub. Date: Jul. 23, 2020

(54) Corrosion Protected Mold Compound

(71) Applicant: Infineon Technologies AG, Neubiberg (DE)

(72) Inventors: Alexander Roth, Zeitlarn (DE); Edmund Riedl, Wald (DE); Stefan Schwab, Regensburg (DE)

(21) Appl. No.: 16/749,425

(22) Filed: Jan. 22, 2020

(30) Foreign Application Priority Data
Jan. 23, 2019 (DE) 102019101631.2

(51) Int. Cl. C08L 63/00; H01L 23/29; C08G 59/68

(52) U.S. Cl. CPC C08L 63/00; C08K 3/013; C08G 59/68; H01L 23/295

(57) ABSTRACT

A mold compound includes the following constituents: a matrix composed of a polymer resin, less than 0.1 weight percent of a free adhesion promoter, based on the total weight of the mold compound, for promoting adhesion of the mold compound, a curing agent for curing the polymer resin, and a catalyst for catalysing formation of the mold compound; and a filler.

### Technical Field

Various embodiments relate generally to a mold compound, a method of preparing a mold compound, a method of use, and an electronic component.

### Background

A conventional package may comprise an electronic chip mounted on a chip carrier such as a leadframe, may be electrically connected by a bond wire extending from. the chip to the chip carrier, and may be molded using a mold compound.

Conventional mold compounds have to fulfill two contradictory tasks: on the one hand, they should adhere to the encapsulated device over the life-time of the device. At the same time, they should not adhere to the mold tool in production.

Conventional mold compounds may use both an adhesion promoter (for the adhesion to the device) and a release agent (to avoid sticking in the mold tool) to try to fulfill both requirements at the same time. However, the presence of the release agent may cause reliability issues over the lifetime. On the other hand, the presence of the adhesion promoter as part of the mold compound can cause the issue of stickiness to the mold tool.

### Summary

There may be a need to provide a mold compound which can be manufactured with low effort, which can be processed in a simple way and which allows manufacturing a product having a high reliability.

According to an exemplary embodiment, a mold compound is provided which comprises the following constituents: a matrix and a filler, where n. the matrix is composed of a polymer resin, less than 0.1 weight percent of a free adhesion promoter for promoting adhesion of the mold compound, a curing agent for curing the polymer resin, and a catalyst for catalysing formation of the mold compound.

According to another exemplary embodiment, a method of preparing a mold compound. is provided, wherein the method comprises grinding and mixing the constituents—having the above-mentioned features—of the mold compound to thereby obtain a grinded mixture, feeding the grinded mixture to an extruder to thereby obtain an extrudate, and powdering the extrudate.

According to another exemplary embodiment, a mold compound having the above-mentioned features is used for at least partially encapsulating an. electronic member.

According to another exemplary embodiment, an electronic component is provided which comprises an electronic chip, and a mold compound having the above-mentioned features encapsulating at least part of the electronic chip.

According to an embodiment, a simplified mold compound is provided. In particular, such a mold compound may be provided with a small or even minimum necessary amount of components or constituents useful. for providing an increased reliability and/or a decrease of risk of failures. In particular when targeting higher junctions of operating and/or testing temperatures for electronic devices, a more robust mold compound may be advantageous. More specifically, it may be advantageous to simplify the mold compound and avoid conventionally used constituents or components at least in conventionally used amounts, which may cause corrosion and/or other issues in the mold compound.

It has been found that an. issue with conventional mold compounds comprising an excessive amount of adhesion promoter is that they may add a contribution or may even be a main driver of corrosion issues inside the device. Thus, it has been found that in particular excessive amounts of adhesion promoter may act as corrosion driver. Highly advantageously, exemplary embodiments reduce the use of free adhesion promoter in a polymer matrix of a mold compound to a lower level. A simplified mold compound. according to an exemplary embodiment may thus be less prone to corrosion, in particular when coming into contact with metallic surfaces in an interior of a package being encapsulated with. the mold compound. As a result, the longtime stability of the mold compound may be improved. Just as an example, such an undesired corrosion may be caused by the creation of sulfide compounds which may be formed based on excessive free adhesion promoter. Metal surfaces which may conventionally be corroded by an adhesion promoter are in particular metallic pads of an encapsulated electronic chip. However, also other metallic surfaces (such as metallic surfaces of a carrier, like a leadframe, and/or an electrically conductive contact element, like a bond wire, bond ribbon or clip) may be reliably prevented from corrosion when free adhesion promoter is reduced to a small value of below 0.1 weight percent. Nevertheless it has turned out that a mold compound according to an exemplary embodiment may properly adhere both to metallic surfaces (compare the examples given above) as well as to nonmetallic surfaces of one or more bodies (for instance a ceramic carrier) encapsulated by the mold compound.

According to an exemplary embodiment, a mold compound is provided which can be manufactured in a simple way and can be properly treated during encapsulating an electronic chip or electronic member or the like. In particular, the provided mold compound may still show a sufficient adhesion with regard to the electronic chip or member so as to prevent an undesired delamination or separation between mold compound based encapsulant and electronic chip or member. At the same time, the provided mold compound shows a sufficiently small adhesion with regard to a mold tool in which the mold compound (and optionally an electronic component to be encapsulated) may be inserted before filling and curing mold compound into the molding chamber. Thus, the mold compound with the optionally encapsulated electronic chip or member can be taken out of the mold tool without the risk that the cured mold compound remains adhering to the surfaces of the mold tool. Thus, the mold compound may be properly handled and may simultaneously ensure a proper encapsulation.

The above-mentioned advantages, in particular in terms of corrosion resistance, may be obtained by a mold compound comprising a polymer resin and a corresponding curing agent for triggering curing of the polymer resin, a filler for adjusting the properties of the mold compound, a catalyst for reducing activation energy and accelerating a chemical curing reaction, and a limited amount of a free adhesion promoter, if desired or required at all. Advantageously, less than 0.1 weight percent of a free adhesion promoter, based on the total weight of the mold compound, may be provided to ensure proper adhesion properties of the mold compound while efficiently suppressing corrosion. At the same time, the adhesion may be sufficiently small so that an encapsulant formed based on the mold compound does not adhere to a mold tool.

In the following, further exemplary embodiments of the mold compound, the methods, and the electronic component will be explained.

Whenever a composition of a mold compound of multiple constituents, elements of items is described within this application, it will be understood by a skilled person. that the individual amounts or contributions of these constituent sum up to 100 weight percent, in relation to or based on the total weight of the mold compound.

In the context of the present application, the term “matrix” may particularly denote a basic material constituted by free adhesion promoter and polymer resin and curing agent and catalyst, within which the remaining constituent (s) of the mold compound may be mixed. In other words, the matrix may be a substance in which the other constituent (s) of the mold compound is or are embedded.

In the context of the present application, the term “free adhesion promoter” may particularly denote a material which can be distributed as a separate or individual constituent or component within the mold compound and which may function for promoting adhesion between the mold compound and one or more bodies (such as an. electronic chip, a carrier, an electrically conductive contact element, etc.) encapsulated by the mold compound. More specifically, such a free adhesion promoter (or coupling agent or bonding agent) may act as an interface between the polymer resin and an encapsulated body to enhance adhesion between these two materials. Since such polymer resin on the one hand and the (in particular inorganic, for instance metallic or ceramic) encapsulated body on the other hand may be different concerning their physical and/or chemical properties (for instance chemical reactivity, surface properties, etc.), forming a direct strong adhesive bond between these two materials may be difficult. An adhesion promoter may however act as a, in a chemical sense, two-terminal interface providing a first connection terminal with the polymer resin and providing a second connection terminal with the encapsulated body to chemically and physically connect these dissimilar materials into a strong bond structure (see also FIG. 2).

In the context of the present application, the term “polymer resin” may particularly denote a substance made of molecules being composed of a plurality of repeated subunits. Polymers are created by polymerization of multiple smaller molecules (which may be denoted as monomers). Polymerization may denote a process of reacting monomer molecules together in a chemical reaction to form polymer chains or three-dimensional networks.

In the context of the present application, the term “curing agent” may particularly denote a substance capable of triggering or promoting curing (in particular hardening) of the polymer resin, in particular by cross-linking of polymer chains thereof. Curing agents can react with epoxy resin via nucleophilic attach. of the oxiran in an equimolar way and also can be scaled down. to lower molarity, as the epoxy function can also react with itself. With the ratio between. epoxy resin and hardener therefore the copolymer chain sequence can be modified, and hence the mechanical and chemical properties.

In the context of the present application, the term “filler” may particularly denote a (in particular powderous or granulate-type) substance filling out interior volumes in the matrix. By the selection of the filler, the physical and/or chemical properties of the mold compound can be adjusted. Such properties may include the coefficient of thermal expansion, the thermal conductivity, the dielectric properties, etc.

In the context of the present application, the term “catalyst” may particularly denote a chemical substance reducing an energetic barrier for a curing reaction of the polymer resin. Moreover, such a catalyst may accelerate the curing reaction.

In an embodiment, the curing agent may be embodied as amines, acids, acid anhydrides, phenols, alcohols and thiols.

In an embodiment, the amount of the free adhesion promoter is zero. In such an embodiment, no free adhesion promoter at all needs to be present in the mold compound. Thus, the composition of the mold compound may be very simple, and an undesired adhesion of the mold compound with regard to an inner surface of a mold tool may be avoided.

In another embodiment, the amount of the free adhesion promoter is above zero, but less than 0.1 weight percent. In particular, the free adhesion promoter may be provided in an amount of less than 0.05 weight percent, based on the total weight of the mold compound. It has turned out that in particular with very moderate amounts of free adhesion promoter (in particular not more than 30 ppm or not more than 40 ppm of the total mold compound), no corrosion issues can be found. Good results in terms of corrosion resistance may be obtained when the weight percentage of the free adhesion promoter, based on the total weight of the mold compound, is in a range between above 0 and below 0.1 weight percent, in particular in a range between 0.02 weight percent and 0.08 weight percent. With the mentioned very small amount of free adhesion promoter, the adhesion between encapsulated electronic chip or member on the one hand and mold compound on the other hand can be promoted.

In an embodiment, the free adhesion promoter comprises at least one of silane and azole, in particular silane and azole. It has turned out that a free adhesion promoter on the basis of silane and/or azole efficiently improves adhesion between an encapsulated electronic chip (in particular a semiconductor die) and the mold compound while keeping the adhesion between and exterior of the mold compound and a mold tool small.

In an embodiment, the free adhesion promoter comprises a silane group, an azole group, and a thiole group. With the mentioned combination of silane, azole and thiol as free adhesion promoter, very good results in terms of the adhesion behavior of the mold compound have been achieved without compromising in terms of corrosion resistance.

In an embodiment, the mold compound further comprises at least one additive. In particular, such at least one additive may have a maximum weight. percentage, based on the total weight of the mold compound, of less than 5 weight percent, in particular less than 1 weight percent. With the addition of one or more additives, the specific properties of the mold compound can be adjusted in accordance with a desired application.

In an embodiment, the at least one additive is selected from a group consisting of a flame retardant, a pigment, a stress modifier, an ion capturer and a release agent. A flame retardant may reduce the tendency of the mold compound to burn in the presence of excessive heat or even fire. The addition of a pigment may allow to adjust the color of the mold compound. For instance, the mold compound may be rendered intransparent so as to avoid any undesired interaction between light and an electronic chip encapsulated within the mold compound. By the addition of a stress modifier, the thermal stress in an interior of a package in form of a molded electronic chip may be adjusted. An ion capturer may capture charged particles in an interior of a package or electronic component so as to ensure a proper electric insulation of the mold compound. The provision of a release agent may promote the simple release of a cured mold compound out of a mold tool.

In an embodiment, the polymer resin is based on an epoxy resin. It has turned out that the use of an epoxy resin is particularly advantageous when designing the mold compound, since it enables a simple processing of the mold compound and is manufacturable with low effort. However, alternative materials for a polymer resin are possible, such as bismaleimide resin, cyanate ester, silicone resin, etc. Such materials may provide a high temperature stability and a low weight loss at high temperatures.

More generally, the polymer resin may comprise or consist of at least one of the group consisting of an epoxy resin, polyimide, poly bismaleimide, silicone, benzoxazine, phenol derivate, and cyanate ester. Other materials are possible as well for the polymer resin.

In an embodiment, the epoxy resin contains a hydroxyl group. Such a hydroxyl group contributes to a simple processability and proper adhesion properties of the mold compound.

In an embodiment, a molar ratio of the epoxy resin and the hydroxyl group is within a range between 0.5 and 1.4, in particular in a range between 0.9 and 1.2. Thus, the molar ratio can be used as a design parameter for further refining the properties of the mold compound.

In an embodiment, the epoxy resin is selected from a group consisting of epoxy o-cresol novolac resin, dicyclopentadiene epoxy resin, multi-aromatic epoxy resin, multi-functional epoxy resin, biphenyl epoxy resin and mixtures thereof. However, other epoxy resins are possible as well.

In an embodiment, the amount of the polymer resin, in particular epoxy resin, is in a range between 0.5 weight percent to 50 weight percent, in particular in a range between 5 weight percent to 25 weight percent (based on the total weight of the mold compound). In particular, the amount of the polymer resin may be smaller than the amount of the filler particles. By taking this measure, the selection of the filler particles may allow to flexibly adjust the properties of the mold compound even with a relatively small amount of polymer resin.

In an embodiment, the amount of the curing agent is between 0.5 weight percent to 50 weight percent, in particular in a range between 0.5 weight percent to 2 weight percent (based on the total weight of the mold compound.). Also quite moderate amounts of curing agent are sufficient for obtaining a proper mold compound. Thus, the opportunity of a material designer of adjusting the properties of the mold compound in accordance with a specific application, namely by correspondingly providing a relatively large amount of filler particles, is high.

In an embodiment, the amount of the filler is in a range between 40 weight percent to 99 weight percent, in particular in a range between 70 weight percent to 96 weight percent (based on the total weight of the mold compound). It may be preferred that the major constituent or the mold compound is the filler. For instance, the filler may be present in the form of filler particles which. may be easily mixed with the other constituents of the mold compound. For instance, it is possible by providing a sufficiently large amount of filler particles in the mold compound to obtain a high thermal conductivity so as to significantly contribute to the removal of heat of the electronic chip embedded within the mold compound during operation of a package or electronic component. It is also possible to improve the dielectric reliability of the mold compound, i.e. to safely prevent an electric current to propagate along or through the mold compound. This may improve the electric reliability of the package or electronic component. However, it is additionally or alternatively possible to also use other filler particles to adjust the properties of the mold. compound, for instance also in terms of its adhesion properties.

In an embodiment, the filler is selected from a group consisting of crystalline silica, fused silica, spherical silica, titanium. oxide, aluminum, hydroxide, magnesium hydroxide, zirconium dioxide, calcium carbonate, calcium silicate, talc, clay, carbon fiber, glass fiber and mixtures thereof. Other filler materials are however possible depending on the demands of a certain application.

In an embodiment, the amount of the catalyst is in a range between 0.2 weight percent to 0.4 weight percent (based on the total weight of the mold compound). Hence, also a quite small amount of catalyst may be sufficient to nevertheless trigger the curing of the mold compound in a short time and at moderate temperature.

In an embodiment, the catalyst is selected from a group consisting of amide compound, phosphine compound, tetraphenylphosphonium adduct, azole compound, triphenyl phosphine, 1,8-dizzabicyclo (5,4,0) undecene-7,2,4 diamino-6 [2′-methylimidazolyl-(1′)]-ethyl-s-triazine, N, N-dimethyl benzyl amine and mixtures thereof. However, also other catalysts may be used.

In an embodiment, the free adhesion promoter is selected from a group consisting of 3-mercapto-1,2,4-triazole, 1-amino-1,3,4-triazole; 3-(glycidoxypropyl) trimethoxy silane, 2- (3, 4-epoxycyclohexyl) ethenyl-trimethoxy silane, 2-propenyl-trimethoxy silane, 2-propenyl-trimethoxy silane, 3-mercapto propyl trimethoxy silane, 3-amino propyl trimethoxy silane, 2-methylimidazole, 4,5-dicarboxyimidazole, 2-mecaptoimidazole and mixtures thereof. It is however also possible to integrate one or more other free adhesion promoters in the mold compound.

In an embodiment, the method further comprises storing the powdered extrudate (or the readily manufactured mold compound before curing) below normal temperature, in particular below 5° C. By cooling the mold compound during storage, maintenance of the above-mentioned advantageous properties of the mold compound can be ensured over a long time. In particular, the adhesion properties may remain advantageous when storing the mold compound below 5° C.

In an embodiment, the method comprises powdering the extrudate by crushing or pulverizing. However, other separation procedures may be implemented as well.

In an embodiment, the electronic component comprises a carrier on which the electronic chip is mounted. For instance, such a carrier may be a leadframe (for instance made of copper), a DAB (Direct Aluminum Bonding), DCB (Direct Copper Bonding) substrate, etc. Also at least part of the carrier may be encapsulated by the mold compound, together with the electronic. Thus, the mention carrier may have a metallic surface which may be prone to corrosion in the presence of an excessive amount of free adhesion promoter. However, in view of the limitation of the free adhesion promoter to less than 0.1 weight percent, the carrier may be encapsulated in the mold compound without the risk of corrosion.

In an embodiment, the filler is provided in the form of filler particles. Filler particles (e.g. SiO₂, Al₂O₃, Si₃N₄, BN, AlN, diamond, etc.) , for instance for improving thermal conductivity may be embedded in an epoxy-based matrix of the encapsulant. However, other filler particles may be implemented in the mold compound as well, in addition or alternatively to the mentioned filler particles. In particular, filler particles may be provided as nanoparticles or microparticles. Filler particles may have identical dimensions or may be provided with a distribution of particle sizes. Such a particle size distribution may be preferred since it may allow for an improved filling of gaps in an interior of the mold compound. For instance, a dimension of the filler particles may be in the range between 1 nm and 200 μm, in particular in a range between 10 nm and 20 μm, more particularly in a range between 2 μm and 5 μm. For instance, the shape of the filler particles may be randomly, spherical, cuboid-like, flake-like, and film-like.

In an embodiment, the filler particles comprise a core at least partially coated by a coating, in particular a polymer resin adhesion promoting coating configured for promoting adhesion to the polymer resin but not to a metal. For instance, the filler particles may be composed of a core surrounded by a coating or shell. Both core and coating may be used for adjusting the physical and/or chemical properties of the filler particles. In particular by the coating, the filler particles may be further functionalized and the properties of the filler may be further refined.

In an embodiment, the coating may be configured as a polymer resin adhesion promoting coating. Such a polymer resin adhesion promoting coating may be configured so as to promote adhesion with the polymer resin only without having an impact on surfaces of one or more bodies embedded in the mold compound. In particular, the polymer resin adhesion promoting coating may not have any impact on metallic surfaces of such bodies, for instance metallic parts of an encapsulated electronic chip, metallic surfaces of a carrier such as a leadframe, or metallic surfaces of a bond wire, bond ribbon or clip. Thus, such a polymer resin adhesion promoting coating neither promotes adhesion nor causes significant, corrosion of the mentioned body surfaces. In contrast to this, the free adhesion promoter forming part of the matrix may promote adhesion with both the polymer resin and with a metal (such as a metallic surface of an. encapsulated body).

In an embodiment, an overall amount of adhesion promoter of the mold compound is less than 0.1 weight percent. Thus, the overall amount of all kinds of adhesion promoters together (in particular free adhesion promoter in the matrix plus optional adhesion promoter in coating of filler particles) may be less than 0.1 weight percent. This ensures obtaining a properly processable and simple mold compound with low tendency of corrosion and with no significant adhesion with regard to a mold tool during production.

In an embodiment, the mold compound comprises less than 0.1 weight percent of a release agent for promoting release of the mold compound out of a mold tool. In the context of the present application, the term “release agent” may particularly denote a substance promoting removability of a cured mold compound or a package comprising a cured mold compound from a mold tool, without undesired adhesion between the mold compound and the surfaces of the mold tool. By limiting the amount of release agent in the mold compound to the mentioned low values, a simple composition of the mold compound may be combined with a proper processability thereof. In an embodiment, no release agent needs to be provided at all.

In an embodiment, the mold compound consists of the polymer resin, the curing agent, the filler, the catalyst, and optionally the free adhesion promoter and/or a release agent. In such an embodiment, no further constituent forms part of the mold compound. Such a mold compound is extremely simple in terms of manufacturing and processing and may nevertheless provide satisfactory results.

In an embodiment, the electronic component comprises an electrically conductive contact element electrically coupling the electronic chip with the carrier. For instance, the electrically conductive contact element may comprise a clip, a wire bond, and/or a ribbon bond. A clip may be a three-dimensionally bent plate type connection element which has two planar sections to be connected to an upper main surface of the respective electronic chip and an upper main surface of the chip carrier, wherein the two mentioned planar sections are interconnected by a slanted connection section. As an alternative to such a clip, it is possible to use a wire bond or ribbon bond which is a flexible electrically conductive wire or ribbon shaped body having one end portion connected to the upper main surface of the respective chip and having an opposing other end portion being electrically connected to the chip carrier.

In an embodiment, the electronic component is configured as one the group consisting of a leadframe connected power module, a Transistor Outline (TO) electronic component, a Quad Flat No Leads Package (QFN) electronic component, a Small Outline (SO) electronic component, a Small Outline Transistor (SOT) electronic component, and a Thin Small Outline Package (TSOP) electronic component. Therefore, the electronic component according to an exemplary embodiment is fully compatible with standard packaging concepts (in particular fully compatible with standard TO packaging concepts) cind appears externally as a conventional electronic component, which is highly user-convenient.

In an embodiment, the electronic component is configured as power module, for instance molded power module. For instance, an exemplary embodiment of the electronic component may be an intelligent power module (IPM). Another exemplary embodiment of the electronic component is a dual inline package (DIP).

In an embodiment, the electronic chip is configured as a power semiconductor chip. Thus, the electronic chip (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide). A semiconductor power chip may comprise one or more field effect transistors, diodes, inverter circuits, half-bridges, full-bridges, drivers, logic circuits, further devices, etc.

In an embodiment, the electronic chip experiences a vertical current flow. The package architecture according to exemplary embodiments is particularly appropriate for high power applications in which a vertical current flow is desired, i.e. a current flow in a direction perpendicular to the two opposing main surfaces of the electronic chip, one of which being used for mounting the electronic chip on the carrier.

As substrate or wafer forming the basis of the electronic chips, a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

Furthermore, exemplary embodiments may make use of standard semiconductor processing technologies such as appropriate etching technologies (including isotropic and anisotropic etching technologies, particularly plasma etching, dry etching, wet etching), patterning technologies (which may involve lithographic masks), deposition technologies (such as chemical vapor deposition (CVD), plasma enhanced chemical vapor deposition (PECVD), atomic layer deposition (ALP), sputtering, etc.).

The above and other objects, features and advantages will become apparent from the following description and the appended claims, taken in conjunction with the accompanying drawings, in which like parts or elements are denoted by like reference numbers.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a cross-sectional view of an electronic component according to an exemplary embodiment to be mounted on a mounting structure.

FIG. 2 schematically illustrates constituents of a mold compound according to an exemplary embodiment.

### DETAILED DESCRIPTION

The illustration in the drawing is schematically and not to scale.

Before exemplary embodiments will be described in more detail referring to the figures, some general considerations will be summarized based on which exemplary embodiments have been developed.

An advantageous composition of a mold compound according to an exemplary embodiment is as disclosed in the following Table 1:

TABLE 1
Composition of a mold compound according to an exemplary
embodiment (all weight percentages in Table 1 are
based on the total weight of the mold compound)

| Item | Possible Material | Weight Percent |
|---|---|---|
| Epoxy | EOCN, epoxy | 3-18% |
| Resin | MAR, PN, etc, | 3-12% |
| system | | |
| Catalyst | TP, DBU, etc. | 0.05-0.5% |
| Filler | Fused or spherical silica, | “Add 100%”, which |
| | alumina, BN, etc. or other | means the rest of |
| | ceramic particle | the mold compound |
| | | is filled with |
| | | filler particles |
| Flame | A10H, Zinc borate, etc. | 0-18% |
| Retardant | | |
| Pigment | Carbon Black, etc. | 0-1% |
| Stress | Silcone Glycidyl Resin, etc. | 0-2% |
| Modifier | | |
| Free | 3-mercapto-1,2,4-triazole, | 0-0.05%, |
| adhesion | 1-amino-1,3,4-triazole; | but in particular |
| promoter | 3-(glycidoxypropyl) | 0% |
| | trimethoxy silane, 2-(3,4- | |
| | epoxycyclohexyl) ethenyl- | |
| | trimethoxy silane, 2- | |
| | propenyl-trimethoxy silane, | |
| | 2-propenyl-trimethoxy | |
| | silane, 3-mercapto propyl | |
| | trimethoxy silane, 3-amino | |
| | propyl trimethoxy silane, 2- | |
| | methylimidazole, 4,5- | |
| | dicarboxyimidazole, 2- | |
| | mecaptoimidazole and | |
| | mixtures thereof. | |
| Release | Carnauba Wax | 0-0.05%, |
| agent | | but in particular |
| | | 0% |

The implementation of above material system, as mold compound, is easily feasible by adjusting the mixture in accordance with the requirements of a certain application.

According to an exemplary embodiment, a mold compound is provided which comprises a polymer resin, a curing agent, a filler, a catalyst, and a free adhesion promoter. Said free adhesion promoter may comprise silane and/or azole. The free adhesion promoter may be present with less than 0.1 weight. percent, in particular none, of the overall mixture.

Optionally, one or more additional additives may be present. Said at least one additive may be selected from the group consisting of flame retardant, pigment, stress modifier, ion capturer and release agent.

More specifically, the polymer resin may be based on an epoxy resin, an epoxy resin, a resin curing agent, a filler, a catalyst, and a free adhesion promoter. An optional additive may be present as well.

Said free adhesion promoter may comprise a silane group, an azole group, and/or a thiole group. The free adhesion promoter may be present with less than 0.1 weight percent, in particular none, of the overall mixture.

For instance, the epoxy resin may constitute 1 to 50% by weight of the total weight of the molding compound, in particular 5 to 25%.

The resin curing agent may constitute 0 to 5% by weight of the total weight of the molding compound, in particular 0.5 to 2%;

In an embodiment, the filler constitutes 40 to 99% by weight of the total weight of the molding compound, in particular 70 to 90%.

The catalyst may constitute 0.05 to 0.5% by weight of the total weight of the molding compound, in. particular 0.2 to 0.4%.

Furthermore, the free adhesion promoter may constitute 0 to 0.05% by weight of the total weight of the molding compound, in particular 0 to 0.08%.

The epoxy resin may contain a hydroxyl group, and the molar ratio of epoxy group and hydroxyl group may be 0.5 to 1.4, in particular 0.9 to 1.2.

The epoxy resin may be chosen from the following substances: epoxy o-cresol novolac resin, dicyclopentadiene epoxy resin, multi-aromatic epoxy resin, multi-functional epoxy resin, biphenyl epoxy resin and mixtures thereof.

The curing agent may be chosen from the following substances: phenolic novolac resin, cresol novolac resin, phenol aralkyl novolac resin, multi-aromatic novolac resin, and multi-functional novolac resin and mixtures thereof.

The filler may be chosen from the following substances: crystalline silica, fused silica, spherical silica, titanium oxide, aluminum hydroxide, magnesium hydroxide, zirconium dioxide, calcium carbonate, calcium silicate, talc, clay, carbon fiber, glass fiber and mixtures thereof.

The catalyst may be chosen from the following substances: amide compound, phosphine compound, tetraphenylphosphonium adduct, azole compound, in particular: triphenyi phosphine, 1,8-dizzabicyclo (5,4, 0) undecene-7,2,4-diamino-6 [2′-methylimidazolyi-(1′)]-ethyl-s-triazine, N,N-dimethyl benzyl amine and mixtures thereof.

The free adhesion promoter may be chosen from the following substances: 3-mercapto-1,2,4-triazole, 1-amino-1, 3,4-triazole ; 3- (glycidoxypropyl) trimethoxy silane, 2- (3,4-epoxycyclohey) ethenyl-trimethoxy silane, 2-propenyl-trimethbxy silane, 2-propenyl-trimethoxy silane, 3-mercapto propyl trimethoxy silane, 3-amino propyl trimethoxy silane, 2-methylimidazole, 4, 5-dicarboxyimida7ole, 2-mecaptoimidazole and mixtures thereof.

In an advantageous embodiment, the above described epoxy mold compound may be prepared by the following procedure: grinding all components of the mold compound to small size and then mixing all components of the mold compound homogeneously, to obtain a pre-mixed resultant; feeding the pre-mixed resultant into an extruder to further mix the pre-mixed resultant, and then crushing or pulverizing the extrudate into a form powder; and optionally storing the powder form extrudate in a cooling place, in particular below a temperature of 5° C.

Advantageously, an epoxy molding compound having the above-mentioned features may be used for electrical encapsulating materials.

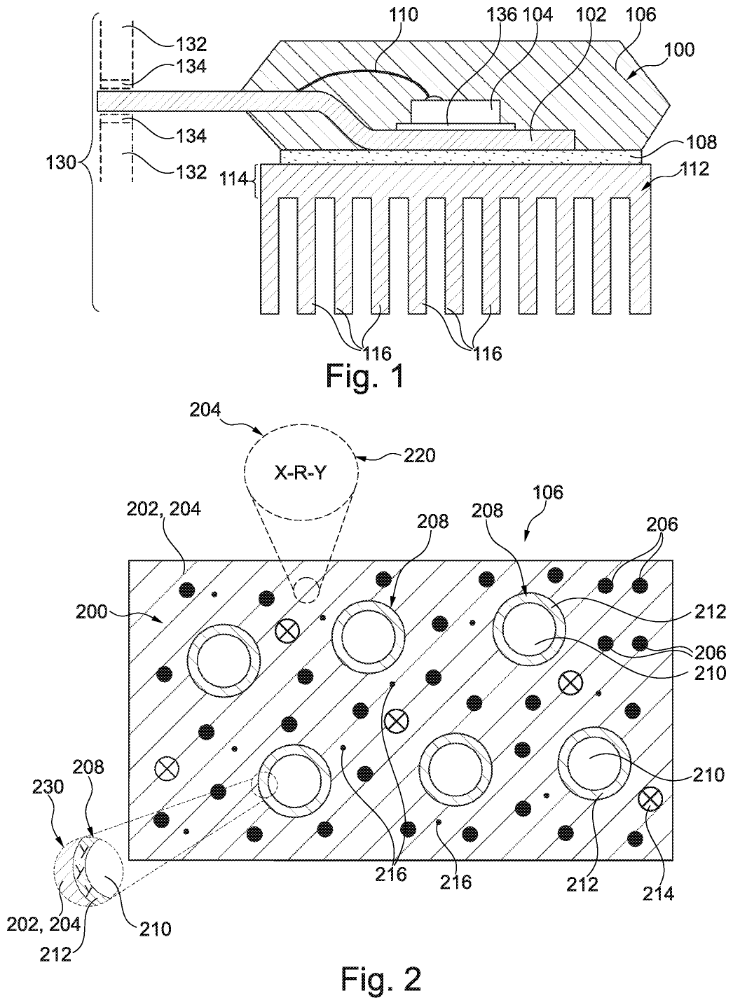

FIG. 1 illustrates a cross-sectional view of an electronic component 100, which is embodied as a Transistor Outline (TO) package, according to an exemplary embodiment. The electronic component 100 is mounted on a mounting structure 132, here embodied as printed circuit board, for establishing an arrangement 130.

The mounting structure 132 comprises an electric contact 134 embodied as a plating in a through hole of the mounting structure 132. When the electronic component 100 is mounted on the mounting structure 132, an electronic chip 104 of the electronic component 100 is electrically connected to the electric contact 134 via an electaily conductive carrier 102, here embodied as a leadframe made of copper, of the electronic component 100.

The electronic component 100 thus comprises the electrically conductive carrier 102, the electronic chip 104 (which is here embodied as a power semiconductor chip) adhesively (see reference numeral 136) mounted on the carrier 102, and an encapsulant in form of a mold compound 106 encapsulating part of the carrier 102 and part of the electronic chip 104. As can be taken from FIG. 1, a pad on an upper main surface of the electronic chip 104 is electrically coupled to the carrier 102 via a bond wire as electrically conductive contact element 110.

During operation of the power package or electronic component 100, the power semiconductor chip in form of the electronic chip 104 generates a considerable amount of heat. At the same time, it shall be ensured that any undesired current flow between a bottom surface of the electronic component 100 and an environment is reliably avoided.

For ensuring electrical insulation of the electronic chip 104 and removing heat from an interior of the electronic chip 104 towards an environment, an electrically insulating and. thermally conductive interface structure 108 may be provided which covers an exposed surface portion of the carrier 102 and a connected surface portion of the mold compound 106 at the bottom of the electronic component 100. The electrically insulating property of the interface structure 108 prevents undesired current flow even in the presence of high voltages between an interior and an exterior of the electronic component 100. The thermally conductive property of the interface structure 108 promotes a removal of heat from the electronic chip 104, via the electrically conductive carrier 102 (of thermally properly conductive copper), through the interface structure 108 and towards a heat dissipation body 112. The heat dissipation body 112, which may be made of a highly thermally conductive material such as copper or aluminum, has a base body 114 directly connected to the interface structure 108 and has a plurality of cooling fins 116 extending from. the base body 114 and in parallel to one another so as to remove the heat towards the environment.

Although FIG. 1 shows a very specific packaging architecture, the use of the mold compound 106 which will be described below in. further detail is advantageous also for any other packaging architectures of electronic components 100, etc.

As will be described below referring to FIG. 2, the mold compound 106 may already comprise a small amount of adhesion promoter for promoting adhesion with chip 104, carrier 102 as well as element 110. At the same time, the amount of adhesion promoter in the mold compound 106 may be kept small to prevent an undesired adhesion between the mold compound 106 of the package or electronic component 100 when. removing the latter out of a mold tool (not shown). A

FIG. 2 schematically illustrates constituents of a mold compound 106 according to an exemplary embodiment which may be used for encapsulation of the electronic component 100 according to FIG. 1.

The mold compound 106 comprises a matrix 200 composed of a polymer resin 202, less than 0.1 weight percent (in relation to or based on the total weight of the mold compound 106) of a free adhesion promoter 204 capable of promoting adhesion of the mold compound 106, as well as a curing agent 206 and a catalyst 214. The polymer resin 202 is the actual material cross-linking during curing the mold compound 106. Furthermore, curing agent 206 may be provided as a further constituent of the matrix 200 which is configured for curing the polymer resin 202, i.e. which actually triggers the above described cross-linking of the polymer resin 202. A filler 208 is here provided as a separate component in additional to the matrix 200 in form of filler particles composed of a core 210 surrounded by an optional coating 212 (in other embodiments of the filler 208, no coating 212 is provided). The material of the core 210 and of the coating 212 may be selected for adjusting the physical and chemical properties of the mold compound 106, such as thermal conductivity, coefficient of thermal expansion, electric insulation, adhesion properties, etc. Additionally, catalyst. 214 as a further constituent of the matrix 200 may be added for catalysing formation of the mold compound 106, more specifically for reducing an activation energy and for accelerating cross-linking of the polymer resin 202 during curing.

The polymer resin 202 may be based on an epoxy resin which contains a hydroxyl group. A molar ratio of the epoxy resin and the hydroxyl group may be within a range between 0.9 and 1.2. For instance, the epoxy resin may be selected from a group consisting of epoxy o-cresol novolac resin, dicyclopentadiene epoxy resin, multi-aromatic epoxy resin, multi-functional epoxy resin, biphenyl epoxy resin and mixtures thereof. The amount of the epoxy resin may be in a range between 5 weight percent to 25 weight percent (in relation to or based on the total weight of the mold compound 106).

The free adhesion promoter 204 may be provided with less than 0.1 weight, percent (in relation to or based on the total weight of the mold compound 106), and can even be zero. The free adhesion promoter 204 may be selected from a group consisting of 3-mercapto-1,2,4-triazole, 1-amino-1,3,4-triazole; 3-(glycidoxypropyl) trimethoxy silane, 2-(3,4-epoxycyciohexyl) ethenyl-trimethoxy silane, 2-propenyl-trimethoxy silane, 2-propenyl-trimethoxy silane, 3-mercapto propyl trimethoxy silane, 3-amino propyl trimethoxy silane, 2-methylimidazole, 4,5-dicarboxyimidazole, 2-mecaptoimidazole, and mixtures thereof.

The amount of the filler 208 may be in a range between 70 weight percent to 99 weight percent (in relation to or based on the total weight of the mold compound 106). For instance, the core 210 of the filler 208 may be selected from a group consisting of crystalline silica, fused silica, spherical silica, titanium oxide, aluminum hydroxide, magnesium hydroxide, zirconium dioxide, calcium carbonate, calcium silicate, talc, clay, carbon fiber, glass fiber and mixtures thereof. The optional coating 212 may for instance be a bound adhesion promoter acting selectively on the polymer resin 202 but not on metallic surfaces, as described below in further detail.

The amount of the curing agent 206 may be between 0.5 weight percent to 2 weight percent. Conventionally known curing agents may be impented.

The amount of the catalyst 214 may in a range between 0.2 weight percent to 0.4 weight percent (in relation to or based on the total weight of the mold compound 106). The catalyst 214 may be selected from a group consisting of amide compound, phosphine compound, tetraphenylphosphonium adduct, azole compound, triphenyl phosphine, 1,8-dizzabicycio (5,4,0) undecene-7,2,4-diamino-6 [2′-methylimidazolyl-(1′)]-ethyl-s-triazine, N,N-dimethyl benzyl amine, and mixtures thereof.

The mold compound 106 may further comprise one or more additives 216. Examples for such additives 216 may be a flame retardant (as a protection against burning), a pigment or coloring agent (for coloring the mold compound 106, for instance carbon black), a stress modifier, an ion capturer or ion getter (in particular a substance being capable of forming a stable compound with ions in an interior of the mold compound 106, for instance ethylenediaminetetraacetic acid (EDTA) or zeolite), a release agent (for promoting releasability of cured mold compound 106 out of a mold tool without undesired adhesion). Releasability may refer to a capability of the mold compound 106 to be ejected or removed from the mold tool without undesired adhesion.

Preparing the mold compound 106 may comprise grinding the above-described constituents (in particular when the constituents are in solid form) and mixing the constituents (in particular the grinded constituents, and optionally one or more remaining liquid constituents such as a liquid polymer resin) to thereby obtain a grinded mixture. Subsequently, the grinded mixture may be fed to an extruder to thereby obtain an extrudate. The extrudate, in turn, may be at least partly powdered by crushing or pulverizing. Advantageously, the obtained extrudate may be stored below 5° C.

By providing the described mold compound 106, sufficient adhesion between the pads (for instance made of copper and/or aluminum) of the electronic chip 104, the carrier 102 (for instance embodied as a copper leadframe) and the contact element 110 (for instance made of copper and/or aluminum) on the one hand and the mold compound 106 on the other hand may be ensured. Simultaneously, it may be possible to prevent excessive corrosion which may be caused by an excessive amount of free adhesion promoter 204. When the electronic component 104, the chip carrier 102, the contact element 110, etc. are encapsulated by the mold compound 106 in a molding procedure, a preform of the mold compound 106 may be inserted, together with the electronic chip 104, the carrier 102 and the contact element 110, in a mold tool (not shown). By curing the mold compound 106, the mold compound 106 encapsulates the electronic component 104 and the chip carrier 102 as well as the contact element 110 with a proper adhesion in between. At the same time, due to the described composition of the mold compound 106, the exterior surface of the mold compound 106 does not adhere strongly to the mold tool before the package or electronic component 100 is removed out of the mold tool. Furthermore, the provided mold compound 106 can be provided with a reliable electric insulation property as well as with a sufficiently high thermal conductivity so as to contribute to the removal of heat out of an interior of the package or electronic component 100 during operation.

In the following, the adhesion promoting functions of the mold compound 106 shall be described in further detail:

As mentioned above, the mold compound 106 according to FIG. 2 comprises (i) a free adhesion promoter 204 in the matrix 200, and (ii) a bound adhesion promoter in the coating 212 of the filler 208. As illustrated schematically in a detail 220 in FIG. 2, the free adhesion promoter 204 is configured for promoting adhesion with. both the polymer resin 202 and with a metallic surface of a respective one of the bodies 102, 104, 110. In contrast to this and now referring to detail 230 in FIG. 2, the polymer resin adhesion promoting coating 212 of the filler 208 only adheres to the polymer resin 102, but not, to the metallic bodies 102, 104, 110. Thus, it may be possible to improve the mechanical stability while not contributing significantly to corrosion. Descriptively speaking, this can be made plausible as follows: As illustrated in detail 220, the free adhesion promoter 204 comprises a chemical rest R and two groups X, Y being active in terms of adhesion promoting. Group X (for instance—HS—) may bind to a metallic surface of one of bodies 102, 104, 110 in terms of adhesion promoting and is thus critical for triggering undesired corrosion. Group Y (for instance—NH₂—) may bind to the polymer resin 202 without having a critical impact on corrosion. Now referring to detail 230, group Y of coating 212 may only bind to the polymer resin 202 without having a critical impact on corrosion as well. Thus, for efficiently suppressing corrosion, it has turned out to be advantageous to limit the amount of the free adhesion promoter 204 to less than 0.1 weight percent, based on the total weight of the mold compound. The only polymer resin adhesion. promoting coating 212 of the filler 208 is however less critical in terms of corrosion resistance.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A mold compound, comprising:
a matrix composed of a polymer resin, less than 0.1 weight percent, based on a total weight of the mold compound, of a free adhesion promoter for promoting adhesion of the mold compound, a curing agent for curing the polymer resin, and a catalyst for catalysing formation of the mold compound; and
a filler.

2. The mold compound of claim 1, wherein an amount of the free adhesion promoter is above zero and less than 0.05 weight percent, based on the total weight of the mold compound.

3. The mold compound of claim 1, wherein the free adhesion promoter comprises at least one of silane, azole, and thiole.

4. The mold compound of claim 1, further comprising at least one additive.

5. The mold compound of claim 1, wherein the polymer resin is an epoxy resin, and wherein an amount of the epoxy resin is in a range between 0.5 weight percent and 50 weight percent, based on the total weight of the mold compound.

6. The mold compound of claim 1, wherein an amount of the curing agent is between 0.5 weight percent and 50 weight percent, based on the total weight of the mold compound.

7. The mold compound of claim 1, wherein an amount of the filler is in a range between 40 weight percent and 99 weight percent, based on the total weight of the mold compound.

8. The mold compound of claim 1, wherein an amount of the catalyst is in a range between 0.2 weight percent and 0.4 weight percent, based on the total weight of the mold compound.

9. The mold compound of claim 1, wherein the polymer resin comprises at least one of an epoxy resin, polyimide, poly bismaleimide, silicone, benzoxazine, phenol derivate, and cyanate ester.

10. The mold compound of claim 1, wherein:
the filler is selected from a group consisting of crystalline silica, fused silica, spherical silica, titanium oxide, aluminum hydroxide, magnesium hydroxide, zirconium dioxide, calcium carbonate, calcium silicate, talc, clay, carbon fiber, glass fiber, and mixtures thereof; and/or
the catalyst is selected from a group consisting of an amide compound, a phosphine compound, a tetraphenylphosphonium adduct, an azole compound, triphenyl phosphine, 1,8-dizzabicyclo (5,4,0) undecene-7,2,4-diamino-6 [2′-methylimidazolyl-(1′)]-ethyl-s-triazine, N,N-dimethyl benzyl amine, and mixtures thereof; and/or
the free adhesion promoter is selected from a group consisting of 3-mercapto-1,2,4-triazole, 1-amino-1,3,4-triazole, 3-(glycidoxypropyl) trimethoxy silane, 2-(3,4-epoxycyclohexyl) ethenyl-trimethoxy silane, 2-propenyl-trimethoxy silane, 2-propenyl-trimethoxy silane, 3-mercapto propyl trimethoxy silane, 3-amino propyl trimethoxy silane, 2-methylimidazole, 4,5-dicarboxyimidazole, 2-mecaptoimidazole, and mixtures thereof.

11. The mold compound of claim 1, wherein the filler is provided in the form of filler particles.

12. The mold compound of claim 11, wherein the filler particles comprise a core at least partially coated by a polymer resin adhesion promoting coating configured for promoting adhesion to the polymer resin but not to a metal.

13. The mold compound of claim 1, wherein the free adhesion promoter is configured for promoting adhesion with the polymer resin and with a metal.

14. The mold compound of claim 1, wherein an overall amount of the free adhesion promoter is less than 0.1 weight percent, based on the total weight of the mold compound.

15. The mold compound of claim 1, further comprising less than 0.1 weight percent, based on the total weight of the mold compound, of a release agent for promoting release of the mold compound out of a mold tool.

16. A method of preparing a mold compound formed from at least the following constituents: a matrix composed of a polymer resin, less than 0.1 weight percent, based on a total weight of the mold compound, of a free adhesion promoter for promoting adhesion of the mold compound, a curing agent for curing the polymer resin, and a catalyst for catalysing formation of the mold compound; and a filler, the method comprising:
grinding and mixing the constituents of the mold compound to obtain a grinded mixture;
feeding the grinded mixture to an extruder to thereby obtain an extrudate; and
powdering the extrudate.

17. The method of claim 16, further comprising:
storing the prepared mold compound below 5° C.; and/or powdering the extrudate by crushing or pulverizing.

18. An electronic component, comprising:
an electronic chip; and
a mold compound encapsulating at least part of the electronic chip, the mold compound comprising:
a matrix composed of a polymer resin, less than 0.1 weight percent, based on a total weight of the mold compound, of a free adhesion promoter for promoting adhesion of the mold compound, a curing agent for curing the polymer resin, and a catalyst for catalysing formation of the mold compound; and
a filler.

19. The electronic component of claim 18, further comprising a carrier on which the electronic chip is mounted, wherein the carrier is at least partially encapsulated in the mold compound.

20. The electronic component of claim 19, further comprising an electrically conductive contact element electrically coupling the electronic chip with the carrier, wherein the electrically conductive contact element is at least partially encapsulated in the mold compound.

21. A mold compound, comprising:
a matrix composed of a polymer resin, a curing agent for curing the polymer resin, and a catalyst for catalysing formation of the mold compound; and
a filler.
